(19) United States
(12) Patent Application Publication
(10) Pub. No.: US 2016/0298882 A1
(43) Pub. Date: Oct. 13, 2016

(54) Heat-flux control and solid-state cooling by regulating chemical potential of photons in near-field electromagnetic heat transfer

(71) Applicant: The Board of Trustees of the Leland Stanford Junior University, Palo Alto, CA (US)

(72) Inventors: Kaifeng Chen, Stanford, CA (US); Parthiban Santhanam, Redwood City, CA (US); Sunil Sandhu, Palo Alto, CA (US); Linxiao Zhu, Stanford, CA (US); Shanhui Fan, Palo Alto, CA (US)

(21) Appl. No.: 15/095,739

(22) Filed: Apr. 11, 2016

Related U.S. Application Data
(60) Provisional application No. 62/145,448, filed on Apr. 9, 2015.

(51) Int. Cl. F25B 21/04; H01L 35/32

(52) U.S. Cl. CPC F25B 21/04; H01L 35/32

(57) ABSTRACT

Solid state near-field radiative cooling from a cold emitter to a hot collector is provided. Two cases are considered. In the first case, the cold emitter is forward biased to drive heat flow from the cold emitter to the hot collector. A surface resonance of the collector is configured to enhance this cooling effect. In the second case, the hot collector is reverse biased to control heat flow from the cold emitter to the hot collector. A surface resonance of the emitter is configured to enhance this cooling effect.

### CROSS REFERENCE TO RELATED APPLICATIONS

This application claims the benefit of U.S. provisional patent application 62/145,448, filed on Apr. 9, 2015, and hereby incorporated by reference in its entirety.

### GOVERNMENT SPONSORSHIP

This invention was made with Government support under contract number DE-SC0001293 awarded by the Department of Energy. The Government has certain rights in the invention.

### FIELD OF THE INVENTION

This invention relates to solid state cooling devices.

### BACKGROUND

Solid state cooling is of general interest for a wide variety of applications. One approach for solid state cooling is radiant cooling, where emission of radiation from the body being cooled is the main cooling mechanism.

Radiant cooling is subject to a limit determined by the black body radiation law for bodies that are separated by a distance large compared to relevant electromagnetic wavelengths. In principle, a larger cooling effect can be obtained for bodies that are in the electromagnetic near-field (i.e., separated by a distance comparable to or smaller than the relevant electromagnetic wavelengths).

However, bodies that are separated by near-field distances can inherently have heat transfer mechanisms that interfere with the desired cooling effect, especially in cases where a cold emitter is to be cooled by radiative heat transfer to a hot collector. Accordingly, it would be an advance in the art to provide suitable structures and methods for such cooling.

### SUMMARY

We have found that it is important to consider the role of surface resonances in near-field thermal transfer devices. In general, such resonances should be configured to enhance the desired cooling effect. Some surface resonances act as a parasitic by providing an undesirable heat flow from the hot collector to the cold emitter. In such cases, it is preferred to suppress the effect of the surface resonances, e.g., by using non-polar materials, by ensuring that emitter and collector resonances have different resonant energies, etc.

In other cases, surface resonances act to enhance the desired cooling effect. In these cases, it is preferred to further enhance the effect of the resonances, e.g., by using polar materials, by ensuring that emitter and collector resonances have equal or approximately equal resonant energies, by micro- or nano-structuring surface(s) in the device to enhance surface resonances, by using a strained structure to enhance surface resonances (e.g., by breaking symmetry), etc.

Two cases are considered. In the first case, positive luminescence, a cold emitter is forward biased to control heat flow from the cold emitter to a hot collector. A surface resonance of the collector is configured to enhance this cooling effect. In the second case, negative luminescence, a hot collector is reverse biased to control heat flow from a cold emitter to the hot collector. A surface resonance of the emitter is configured to enhance this cooling effect. Thus in general there is a biased structure and an unbiased structure that are radiatively coupled to each other.

The biased structure can be a wide range of semiconductors including GaAs, GaN, and InGaN. The unbiased structure need not be a semiconductor. The only requirement is that the unbiased structure needs to have strong radiative coupling with the biased structure. Thus the unbiased structure can have a wider range of material choices. The preferred choices for materials for the unbiased structure include semiconductors like GaAs, GaN, InGaN, and also metals like ITO, and oxides, and quantum dots like CdSe/CdS quantum dot.

This work provides an important, previously unexplored mechanism for solid-state cooling. Significant advantages are provided, such as high efficiency (i.e., close to the Carnot limit), high cooling power density, small size and simple geometry.

### BRIEF DESCRIPTION OF THE DRAWINGS

FIGS. 1A-B show two embodiments of the invention.

FIGS. 2A-B schematically show two kind of surface resonance.

FIGS. 2C-D schematically show examples of intersubband structures suitable for use in embodiments of the invention.

FIG. 3 shows the configuration for section A of the detailed description.

FIG. 4 shows ideal net cooling power density and coefficient of performance for the configuration of section A.

FIG. 5A shows net cooling power density including the effects of Auger recombination and phonon-polariton heat transfer for the homomaterial configuration of section A.

FIG. 5B shows net cooling power density including the effects of Auger recombination and phonon-polariton heat transfer for the heteromaterial configuration of section A.

FIG. 6 shows the effect of Auger recombination for the configuration of section A.

FIG. 7 shows further details of the effect of Auger recombination for the configuration of section A.

FIG. 8 shows the effect of phonon-polariton heat transfer for the configuration of section A.

FIGS. 9A-B show further details of the effect of phonon-polariton heat transfer for the configuration of section A.

FIG. 10 shows the configuration for section B of the detailed description.

FIG. 11 shows ideal net cooling power density and coefficient of performance for the configuration of section B.

FIG. 12 shows the effect of Auger recombination for the configuration of section B.

FIG. 13 shows the effect of sub-bandgap heat transfer for the configuration of section B.

### DETAILED DESCRIPTION

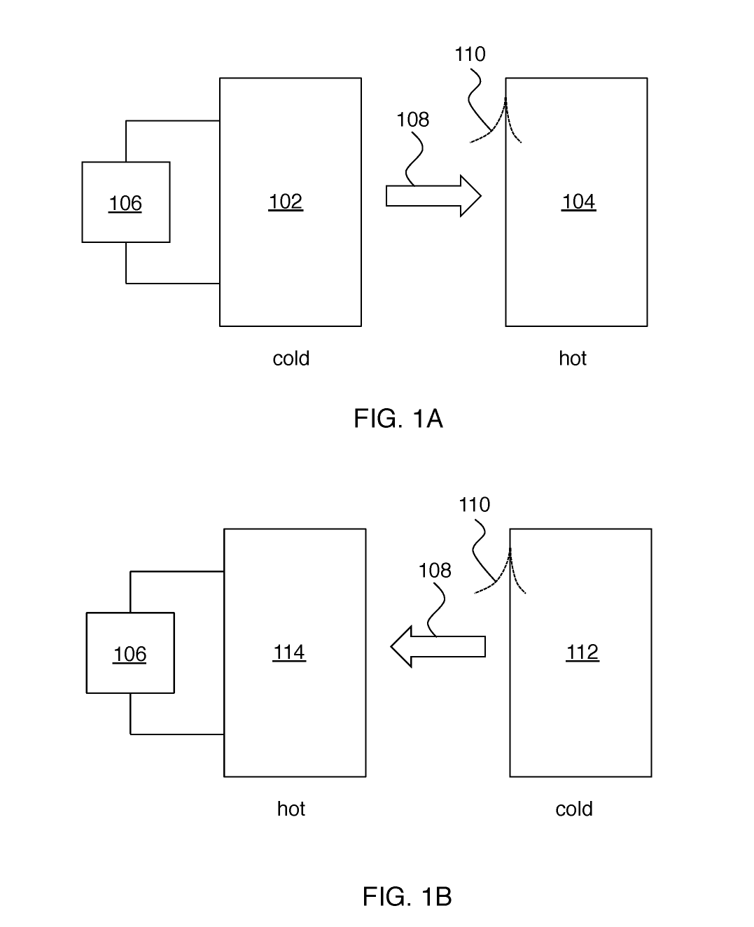

FIG. 1A shows a first embodiment of the invention. In the solid state heat transfer device of this example, an emitter 102 has an emitter temperature T_{C}. A collector 104 has a collector temperature T_{H}, where T_{C}<T_{H}. Thus the collector is hotter than the emitter as shown on the figure. Emitter 102 includes a semiconductor structure configured to emit electromagnetic radiation on application of a forward bias from bias source 106. Practice of the invention does not depend critically on details of this semiconductor structure, so it is not separately shown on the figure. Suitable semiconductor structures include, but are not limited to: p-n junctions, p-i-n structures, and intersubband transition structures. A near-field radiative heat flow 108 from the emitter to the collector is controlled by the forward bias from bias source 106.

Collector 104 has a surface resonance 110 configured to provide enhanced net heat transfer from the emitter to the collector. Here the dashed lines depict the position dependent field strength of typical surface resonances. Thus this device provides cooling by heat transfer from a relatively cold emitter to a relatively hot collector. It is convenient to refer to this case as the positive luminescence case.

Preferably, the resonant energy of surface resonance 110 is greater than or equal to the bandgap of emitter 102. In such cases, the effect of the surface resonance is to provide enhanced near-field heat flow from the emitter to the collector (i.e., enhanced cooling), and it is therefore further preferred to enhance the effect of surface resonance 110. Approaches for enhancing the effect of surface resonance 110 include, but are not limited to: selecting a polar material for collector 104 (e.g., compound semiconductors) to increase the effect of the surface phonon-polariton resonance, nano-structuring or microstructuring the surface of collector 104 to enhance the surface resonance, and including a strained structure in collector 104 to enhance the surface resonance (e.g., by breaking symmetry).

However, it is not always possible in practice to ensure that the resonant energy of surface resonance 110 is greater than the bandgap of emitter 102. If the resonant energy of surface resonance 110 is less than the bandgap of emitter 102, the effect of surface resonance 110 is to increase a parasitic and undesirable heat flow from the collector to the emitter (i.e., reduced cooling). Therefore, it is preferred in such cases to reduce the effect of surface resonance 110 on heat transfer between the emitter and the collector. Approaches for reducing the effect of surface resonance 110 include, but are not limited to: selecting a non-polar (or relatively low polarity) material for collector 104 to eliminate (or decrease) the effect of the surface phonon-polariton resonance, and selecting materials for the emitter and collector such that any surface resonance that may be present on emitter 102 is mismatched in energy relative to surface resonance 110 on collector 104.

FIG. 1B shows a second embodiment of the invention. In the solid state heat transfer device of this example, an emitter 112 has an emitter temperature T_{C}. A collector 114 has a collector temperature T_{H}, where T_{C}<T_{H}. Thus the collector is hotter than the emitter as shown on the figure. Collector 114 includes a semiconductor structure configured to provide enhanced absorption of electromagnetic radiation on application of a reverse bias from bias source 106. Practice of the invention does not depend critically on details of this semiconductor structure, so it is not separately shown on the figure. Suitable semiconductor structures include, but are not limited to: p-n junctions, p-i-n structures, and intersubband transition structures. A near-field radiative heat flow 108 from emitter 112 to collector 114 is controlled by the reverse bias from bias source 106.

Emitter 112 has a surface resonance 110 configured to provide enhanced net heat transfer from the emitter to the collector. Here the dashed lines depict the position dependent field strength of typical surface resonances. Thus this device also provides cooling by heat transfer from a relatively cold emitter to a relatively hot collector. It is convenient to refer to this case as the negative luminescence case.

Preferably, the resonant energy of surface resonance 110 is greater than or equal to the bandgap of collector 114. In such cases, the effect of the surface resonance is to provide enhanced near-field heat flow from the emitter to the collector (i.e., enhanced cooling), and it is therefore further preferred to enhance the effect of surface resonance 110. Approaches for enhancing the effect of surface resonance 110 include, but are not limited to: selecting a polar material for emitter 112 (e.g., compound semiconductors) to increase the effect of the surface phonon-polariton resonance, nano-structuring or microstructuring the surface of emitter 112 to enhance the surface resonance, and including a strained structure in emitter 112 to enhance the surface resonance (e.g., by breaking symmetry).

However, it is not always possible in practice to ensure that the resonant energy of surface resonance 110 is greater than the bandgap of collector 114. If the resonant energy of surface resonance 110 is less than the bandgap of collector 114, the effect of surface resonance 110 is to increase a parasitic and undesirable heat flow from the collector to the emitter (i.e., reduced cooling). Therefore, it is preferred in such cases to reduce the effect of surface resonance 110 on heat transfer between the emitter and the collector. Approaches for reducing the effect of surface resonance 110 include, but are not limited to: selecting a non-polar (or relatively low polarity) material for emitter 112 to eliminate (or decrease) the effect of the surface phonon-polariton resonance, and selecting materials for the emitter and collector such that any surface resonance that may be present on collector 114 is mismatched in energy relative to surface resonance 110 on emitter 112.

Here near-field radiative heat flow is radiative heat flow between points which are separated by a distance on the order of a wavelength corresponding to the band gap of the biased emitter (for the positive luminescence case) and corresponding to the band gap of the biased collector (for the negative luminescence case). In most practical cases this amounts to a separation of about 20 microns or less.

As indicated above, forward bias is any electrical bias that tends to increase radiative emission from a semiconductor structure, relative to the radiation emitted from the semiconductor structure when it is in thermal equilibrium. Reverse bias is any electrical bias that tends to decrease radiative emission from a semiconductor structure, relative to the radiation emitted from the semiconductor structure when it is in thermal equilibrium.

More specifically forward bias leads to a distortion of carrier densities in the upper and lower states connected by a radiative transition where application of a forward bias voltage increases the quantity f_{upper}*(1−f_{lower}), where f denotes the Fermi occupation. Reverse bias means an increase in the quantity f_{lower}*(1−f_{upper}) for at least one radiative transition on application of a reverse bias voltage.

Practice of the invention does not depend critically on the type of surface resonance present on collector 104 or on emitter 112. Suitable resonance types include, but are not limited to: surface plasmons and surface phonon-polaritons.

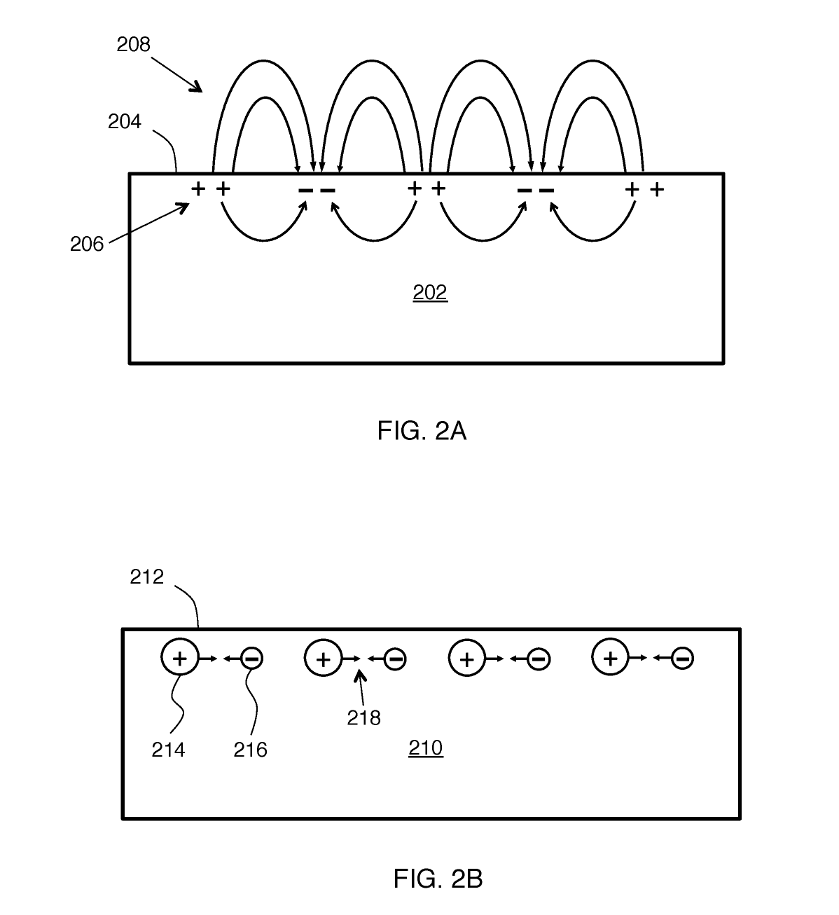

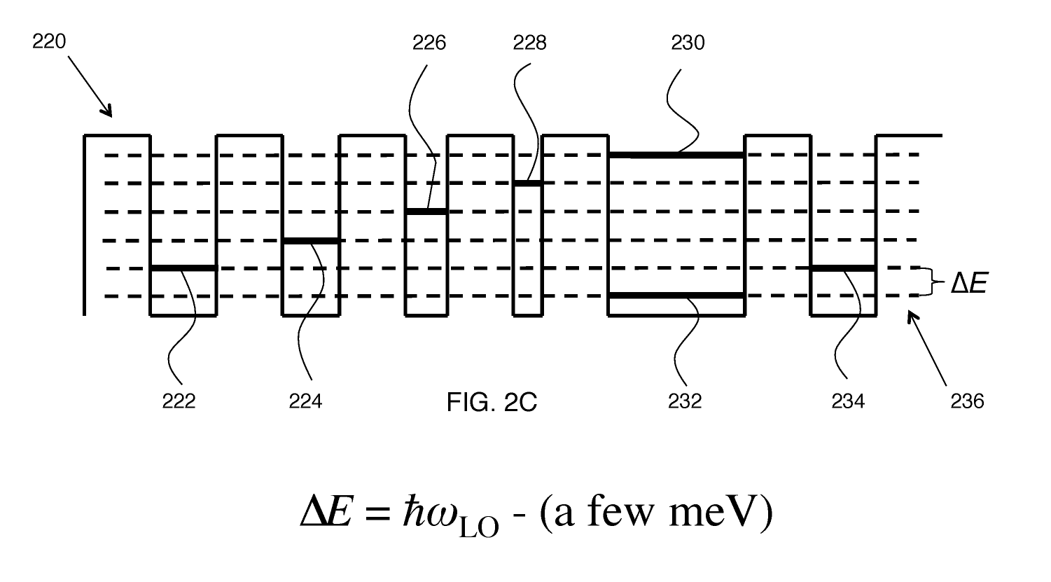

FIG. 2A illustrates a surface plasmon resonance. Line 204 denotes the boundary between solid 202 and its ambient surroundings. Positive and negative electric charges 206 (e.g., electrons and holes in a semiconductor) are free to move within the solid. Their dielectric response to externally applied fields at frequencies of interest leads to a negative real part of the permittivity. The electric field lines 208 within the solid 202 and in the ambient surroundings can support a surface resonance with continuous perpendicular D field.

FIG. 2B illustrates a phonon polariton surface resonance. Line 212 denotes the boundary between solid 210 and its ambient surroundings. The electronegativity difference between adjacent atoms 214 and 216 within a polar crystal allow the degrees of freedom associated with their relative motion, indicated by arrows 218, to couple external electromagnetic fields to the vibrational energy of the solid. This coupling leads to a frequency-dependent dielectric permittivity with a negative real part, which in turn supports a surface resonance.

Here a polar material is any solid material in which there is a net charge transfer between neighboring atoms in the solid. In such materials, relative motion of the atoms from mechanical vibration inherently provides an oscillating dipole which can strongly couple to electromagnetic radiation. The greater the change transfer between atoms (i.e., the greater the electronegativity difference of neighboring atoms), the stronger this coupling becomes.

In a non-polar material (e.g., silicon), there is no net charge transfer between neighboring atoms in the solid. In such materials, motion of the atoms from mechanical vibration is much more weakly coupled (or not coupled at all) to electromagnetic radiation because the mechanical motions don't provide an oscillating dipole.

Section A below provides further details relating to the positive luminescence case, where the emitter is forward biased to enhance heat flow from a cold emitter to a hot collector. Section B below provides further details relating to the negative luminescence case, where the collector is reverse biased to enhance heat flow from a cold emitter to a hot collector.

One non-limiting example of a semiconductor body is an inter-subband device formed by the layering of differing lattice-matched alloys such as Al_{0.3}Ga_{0.7}As and GaAs. For such a body, the transition under bias could be between subbands in the conduction band of the Multi-Quantum Well (MQW) structure. This transition could be used in cooling under both the positive luminescence and negative luminescence scenarios.

In the negative luminescence case, a reverse bias should rapidly remove carriers from the Upper Radiative (UR) state and/or rapidly add carriers to the Lower Radiative (LR) state. If a body with a surface resonance matching the energy difference between the UR and LR states is brought into the near field, cooling of that surface should occur. FIG. 2C schematically shows an exemplary intersubband structure for this case. Here 230 is the UR state and 232 is the LR state. Other confined quantum well states are referenced as 222, 224, 226, 228, and 234. The energy levels 236 are spaced by the AlGaAs optical phonon energy minus a few milli-electron volts. This energy spacing is designed so that as electrons are driven through the structure from right to left, the adjacent wells will experience resonant optical phonon emission to speed up the flow of electrons from 230 to 228, 228 to 226, and so on until the carriers flow into the LR state of the adjacent period. The energy spacing serves to rapidly depopulate the UR state and rapidly populate the LR state.

In the positive luminescence case, a forward bias should rapidly add carriers to the Upper Radiative (UR) state and/or rapidly remove carriers from the Lower Radiative (LR) state. If a body with a surface resonance matching the energy difference between the UR and LR states is brought into the near field, cooling of the inter-subband device should occur. FIG. 2D schematically shows an exemplary intersubband structure for this case. Here 230 is the UR state and 232 is the LR state. Other confined quantum well states are referenced as 222, 224, 226, 228, and 234. The energy levels 236 are spaced by the optical phonon energy plus a few milli-electron volts. This energy spacing is designed so that as electrons are driven through the structure from left to right, the adjacent wells will experience resonant optical phonon absorption to speed up the flow of electrons from 228 to 230, 226 to 228, and so on until the carriers flow into the UR state from the LR state of the adjacent period. The energy spacing serves to rapidly populate the UR state and rapidly depopulate the LR state.

### A) Positive Luminescence

### A1) Introduction

Near-field electromagnetic heat transfer through vacuum has been of fundamental importance because the power density of the energy flow can be enhanced beyond Planck's law of blackbody radiation. In recent years, such enhancement has been demonstrated experimentally. Theoretical explorations of increasingly complex geometries are widely discussed. Moreover, there has been growing interest in active control of near-field heat transfer.

In previous works on near-field heat transfer between two bodies, one assumes a zero chemical potential for the objects involved. However, photons can have a chemical potential when they are in quasi-equilibrium with a semiconductor under external bias. Yet the consequences of such non-zero chemical potential for near-field heat transfer have not been explored previously. In this section, based on the fluctuational electrodynamics formalism, we provide a direct calculation of near-field heat transfer between two bodies, each taken to be in quasi-equilibrium, in the presence of a non-zero chemical potential. We show that the use of such chemical potential enables electronic control of near-field heat transfer.

Furthermore, when considering heat transfer between cold and hot objects, applying a chemical potential on the cold object can result in a net heat flow from the cold to the hot object, and hence the resulting structure can be used for cooling purposes. Therefore, near-field heat transfer in the presence of non-zero chemical potential provides an important, previously unexplored mechanism for solid-state cooling. We show that in the ideal limit, such a cooling device can have an efficiency that approaches the Carnot efficiency. We also consider the effect of intrinsic non-idealities, including non-radiative Auger recombination and parasitic heat transfer through surface phonon-polaritons. We show that the structure can still provide cooling with reasonable efficiency, in spite of these non-idealities, with a heteromaterial design having two different semiconductors.

### A2) The Configuration and Formalism

### A2.1) The Configuration

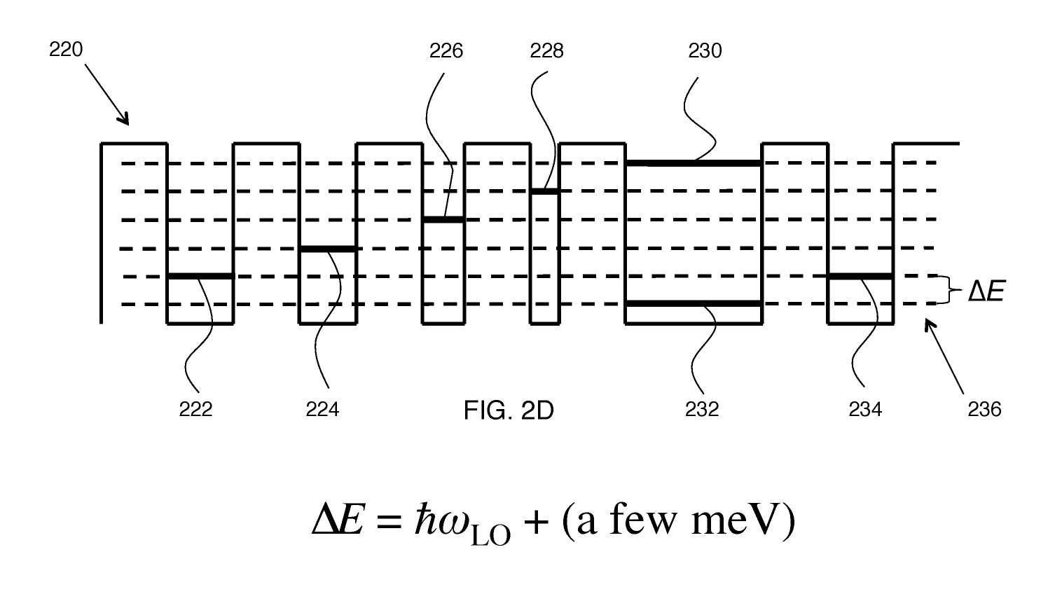

Throughout the paper, we consider the configuration in FIG. 3, where two intrinsic semiconductors, labeled bodies 1 and 2, with thickness t₁ and t₂ respectively, are brought into close proximity with a vacuum gap separation d. Here d is much smaller than the extent of bodies 1 and 2 in the dimensions transverse to the gap. The temperatures of the two bodies are labeled T₁ and T₂ (T₁<T₂), respectively. To control the chemical potential of each semiconductor, we assume that the back side of each intrinsic semiconductor region forms a junction with small heavily doped p⁺ or n⁺ region, which then connects to external contacts. The two-body structure is enclosed within perfect mirrors at the extreme left and right boundaries. Depictions of the relevant bands and the corresponding quasi-Fermi levels of the two semiconductors are also included in the figure. With an external forward bias V applied to body 1, the quasi-Fermi levels for its electrons and holes are separated by ΔE_{F}=qV. Throughout this section, we choose T₁=290K, T₂=300K.

For each body, assuming perfect contacts, the quasi-Fermi level of the electrons in the intrinsic region is set by the potential at the n-type contact while that of the holes is set by the p-type contact. Taking the body to be optically thick for photons with frequencies above the band gap energy, the resulting non-equilibrium state of the electron-hole system gives rise to an outgoing photon field from interband transitions with a chemical potential qV. For simplicity, we apply zero voltage to body 2, i.e. we short body 2 for the calculations in this paper so it has ΔE_{F}=0.

Intuitively, when compared to the case without applied voltage, one should expect increased photon emission from body 1 as one applies a forward-bias voltage on it. Thus, the near-field heat transfer between the two bodies can be influenced by the applied voltage. Moreover, in the case where body 1 is colder than body 2, such an increased photon emission may nevertheless result in a net heat flow from body 1 to body 2. Hence by using electrical work as delivered by an applied voltage, one could pump heat from a cold body to a hot body. The objective of this paper is to study such electronically controlled heat transfer in detail, and to evaluate its performance as a solid-state cooling device.

### A2.2) Dielectric Function and Current Fluctuations of Semiconductors Under External Bias

We study the system shown in FIG. 3 using the formalism of fluctuational electrodynamics. In this formalism, one describes the heat transfer between objects by computing the electromagnetic flux resulting from fluctuating current sources inside each object. The magnitude of the current fluctuation is related to the imaginary part of the dielectric function of the object. Therefore, we start with a brief discussion of the dielectric function and the corresponding current fluctuation of a semiconductor under external bias. Since we will primarily be considering a temperature range near room temperature, we will consider narrow-band gap semiconductors such as InAs and InSb whose band gaps are 0.354 eV and 0.17 eV at room temperature, respectively.

The dielectric function of such III-V semiconductors has contributions from both interband electronic transitions at frequencies above the band gap and from phonon-polariton excitations at frequencies well below the band gap. We denote the contributions to the dielectric function from the electronic transitions and the phonon-polariton excitations as ∈ₑ(ω,V) and ∈ₑ(ω), respectively. The overall dielectric function has contributions from these two processes

$$ε ( ω , V ) = \{ \begin{matrix}{ε}_{e} ( ω , V ) & ( ω \geq {ω}_{c} ) \\ {ε}_{p} ( ω ) & ( ω < {ω}_{c} )\end{matrix} , \qquad ( A1 )$$

where ωₑ is the cut-off frequency between interband electronic transitions and phonon-polariton excitations. In our calculations, we choose ωₑ to be somewhat below the electronic band gap frequency where the imaginary part of the dielectric function is near-zero.

For narrow band gap semiconductors, a forward bias will easily shift the quasi-Fermi levels towards the degenerate regime where the Boltzmann approximation of electron occupation fails. This will result in a significant change in the imaginary part of ∈ₑ(ω,V), denoted as ∈e″(ω,V), as a function of external bias. For degenerate semiconductors, it is known that ∈e″(ω,V) is related to V only through \hat{n}ᵥ−\hat{n}_{c}. Here \hat{n}_{C} and \hat{n}ᵥ are the average occupation numbers for the conduction band edge states and valence band states, respectively, that satisfy the vertical transition condition at the frequency ω. Therefore

$${ε}_{n}^{″} ( ω , V ) = \frac{( {\overline{n}}_{v} - {\overline{n}}_{c} )}{( {\overline{n}}_{v} - {\overline{n}}_{c} ) {\vert}_{V = 0}} {ε}_{e}^{″} ( ω , 0 ) . \qquad ( A2 )$$

As we vary the voltage, the change in the real part of ∈ₑ(ω,V) is generally quite small, and is therefore ignored in our calculations.

In the presence of external bias, photons emitted from interband transitions can carry a non-zero chemical potential. Consider a semiconductor whose electronic degrees of freedom (i.e. its electrons and holes) are excited by an external voltage V, maintained at a temperature T. The quasi-Fermi levels of the electrons and holes are separated by qV, where q is the magnitude of the electron's charge. A photon gas in equilibrium with such a semiconductor through electronic interband transitions then satisfies the Bose-Einstein distribution

$$Θ ( ω , T , V ) = \frac{ℏω}{exp ( \frac{ℏω - qV )}{{k}_{B} T} ) - 1} , \qquad ( A3 )$$

where Θ(ω,T,V) is the expectation value of photon energy in a single mode at angular frequency ω, h is the reduced Planck constant and k_{B} is the Boltzmann constant. In Eq. A3, qV plays the role of chemical potential for photons. Using the fluctuation-dissipation theorem, the thermal electromagnetic fields as generated by interband transitions can then be described by random thermal current sources jₐ(r,ω) in the semiconductor with the correlation function

$${〈 {j}_{α} ( r , ω ) {j}_{β}^{*} ( {r}^{′} , {ω}^{′} ) 〉}_{c} = \frac{4}{π} ωΘ ( ω , T , V ) δ ( r - {r}^{′} ) δ ( ω - {ω}^{′} ) {ε}_{e}^{″} ( ω , V ) {δ}_{αβ} , \qquad ( A4 )$$

where α and β label the directions of polarization, r and r′ are position vectors and δ(ω−ω′) is the Dirac delta function. This expression can be derived using linear response theory and Kubo's formula. The derivation assumes that the electromagnetic fields are weak. In practice, Eq. A4 is valid when

$$\frac{{E}_{g} - qV}{{k}_{B} T} >> 1 ,$$

and hence the system is in the spontaneous emission regime. Eq. A4 is no longer applicable when the applied voltage V is comparable or even greater than E_{g}/q, in which case strong stimulated emission or even lasing can occur and the weak-field assumption is no longer valid.

In addition to the electronic transition, III-V semiconductors also can couple electromagnetically via polaritons with angular frequencies corresponding to their polar optical phonon bands. The bulk phonon-polariton energies for InAs and InSb are 0.0276 eV and 0.025 eV, respectively. As we will see, the presence of these phonon polaritons also contributes significantly to the energy transfer between the semiconductors. The imaginary part of the dielectric function in this frequency range is denoted as ∈ₚ″(ω) and is independent of external bias. Using the fluctuation-dissipation theorem, the correlation function of the random sources due to phonon-polariton excitations is then

$${〈 {j}_{α} ( r , ω ) {j}_{β}^{*} ( {r}^{′} , {ω}^{′} ) 〉}_{p} = \frac{4}{π} ωΘ ( ω , T , 0 ) δ ( r - {r}^{′} ) δ ( ω - {ω}^{′} ) {ε}_{e}^{″} ( ω ) {δ}_{αβ} . \qquad ( A5 )$$

Unlike the random current sources corresponding to electronic interband transition in Eq. A4, here the magnitude of the fluctuation is independent of the external voltage. Combining Eqs. A4 and A5 allows us to treat the electromagnetic near-field heat transfer between semiconductors under external bias, taking into account the intrinsic dissipation mechanisms of these materials. Note that the phonon-polariton frequencies are far below the bandgap frequencies, which justifies the separate treatment of electronic transitions and phonon-polariton excitations in Eq. A1.

### A2.3) Electromagnetic Formalism

We use the standard dyadic Green's function technique to compute the transferred power density from the current fluctuation presented in Section A2.2. We compute separately the two non-overlapping emitted photon energy flux spectra Φₑ(ω) and Φₚ(ω) associated with photons emitted from above-bandgap electronic transitions and phonon-polariton excitations, respectively. The energy fluxes Eₑ and Eₚ, for above and below band gap photons, respectively, are then obtained by integration over the appropriate frequency ranges

E_{a→b}^{e}=∫_{ω}_{_{c}}^{→∞}θ(ω,Tₐ,Vₐ)Φₑ(ω)dω, (A6)

E_{a→b}^{p}=∫₀^{ω}^{_{c}}θ(ω,Tₐ,0)Φₚ(ω)dω. (A7)

The subscripts (a,b) in Eqs. A6 and A7 can be either (1,2) or (2,1) depending on the flux direction (FIG. 3). In Eqs. A6 and A7, ω_{c} is as defined in Eq. A1. We attribute the transfer at frequencies above this frequency to interband electronic transition and below it to phonon-polariton excitations, respectively. The overall heat transfer between the two bodies is

E_{a→b}=E_{a→b}^{e}+E_{a→b}^{p}. (A8)

A similar calculation also yields the above-bandgap photon flux between the two bodies as

$${F}_{a \to b} = {\int }_{{ω}_{e}}^{+ ∞} \frac{Θ ( ω , {T}_{a} , {V}_{a} )}{ℏω} {Φ}_{e} ( ω ) d ω . \qquad ( A9 )$$

For later use, we define

F_{a→b}⁰=F_{a→b|V}_{ₐ}₌₀. (A10)

### A2.4) Detailed Balance Relations

The formalism described in Section A2.3 enables us to compute the dependence of heat power transfer rate as a function of applied voltage. In order to further evaluate the performance of such a configuration for cooling purposes, we need to calculate the injected electric power density into body 1. This electric power density is just the product of the external bias V and the injected current density J to body 1. By detailed balance, the current density J must be related to the total recombination rate as

J=q(F_{1→2}−F_{2→1}+R), (A11)

where F_{1→2} and F_{2→1} are defined in Eq. A9. (F_{1→2}−F_{2→1}) and R represent the net radiative recombination rate and non-radiative rate, respectively, per unit area in body 1. In this section, for non-radiative recombination, we consider only the Auger process, which is intrinsic and dominates in high-quality materials. Because of our short circuit condition on Body 2, the computations in this section will require considering the Auger process only in InAs. Here we set R in Eq. A11 to

R=(Cₙn+Cₚp)(np−nᵢ²)t₁, (A12)

where n and p are the electron and hole concentrations, respectively, and t₁ is the thickness of body 1. At 290K, for InAs, C₀=Cₚ+Cₙ=2.26×10⁻²⁷ cm⁶·s⁻¹ is the Auger recombination coefficient. nᵢ=6.06×10¹⁴ cm⁻³ is the intrinsic carrier concentration at 290K. Having computed the injected current into body 1, we then obtain the net outflow power density from body 1.

P=(E_{1→2}−E_{2→1})−JV. (A13)

### A3) Ideal Case

Using the formalism in Section A2, we now consider the heat transfer in the configuration shown in FIG. 3, when an external bias voltage is applied to body 1. In this section, we first consider the ideal case, where we ignore the contributions from non-radiative recombination (R=0 in Eq. A11) and phonon-polariton excitations (E_{a→b}^{p}=0 in Eq. A8). In such an ideal case, we introduce an analytical model for heat transfer, first in Section A3.1 for the homomaterial structure where the two semiconductors are the same, and then in Section A3.2 for the heteromaterial structure where the two semiconductors are different. For both structures, the analytical model predicts an exponential dependence of the heat transfer power as a function of voltage. The model also predicts that in the ideal case the efficiency of this configuration as a cooling device can approach the Carnot limit. We show in Section A3.3 that the prediction of such an analytical model agrees very well with direct computations based on the fluctuational electrodynamics formalism.

### A3.1) Analytical Model for Homomaterial Structure

We consider the homomaterial structure first. In our model, we assume

$$exp ( \frac{{ℏω}_{g} - qV}{{k}_{B} T} ) >> 1. \qquad ( A14 )$$

Under this condition, the emission spectra of the semiconductors are strongly peaked near the band gap frequency ω_{g} of the semiconductor. Thus from Eq. A9 we have the photon flux

$${F}_{1 \to 2} = exp ( \frac{qV}{{k}_{B} {T}_{1}} ) {F}_{1 \to 2}^{0} . \qquad ( A15 )$$

Furthermore, Eq. A6 can be simplified as

$$\begin{matrix}{E}_{1 \to 2}^{e} = exp ( \frac{qV}{{k}_{B} {T}_{1}} ) {ℏω}_{g} {F}_{1 \to 2}^{0} , & ( A16 ) \\ {E}_{2 \to 1}^{e} = {ℏω}_{g} {F}_{2 \to 1}^{0} . & ( A 17 )\end{matrix}$$

Therefore, we see that the transferred power has an exponential dependency on the applied voltage.

We now consider the cooling performance of this configuration. From Eqs. A9 and A11, the current density in body 1 in the presence of external voltage V is

$$J = q ( {e}^{\frac{qV}{{k}_{B} {T}_{1}}} {F}_{1 \to 2}^{0} - {F}_{2 \to 1}^{0} ) . \qquad ( A18 )$$

Using Eq. A13 and combining it with Eqs. A16-A18, the net outflow power density from body 1 is then

$$P = ( {e}^{\frac{qV}{{k}_{B} {T}_{1}}} {F}_{1 \to 2}^{0} - {F}_{2 \to 1}^{0} ) ( {ℏω}_{g} - qV ) . \qquad ( A19 )$$

For cooling purpose, one sets T₁<T₂. In the absence of external voltage, F_{1→2}⁰<F_{2→1}⁰, i.e. there is a net inflow of power to the cold body 1, as required by the Second Law of Thermodynamics. With the application of voltage, however, there is an exponential increase of the radiative power from body 1. As a result, P in Eq. A19 may change sign, indicating a net outflow of power from the cold body 1 to the hot body 2 and hence the possibility of cooling.

The voltage where P=0 defines the threshold voltage Vₜ. In this model, the condition of P=0 coincides with J=0 at the threshold voltage Vₜ. Therefore, based on Eqs. A6 and A13 we have

θ(ω_{g},T₁,V₁)=θ(ω_{g},T₂,0), (A20)

from which we obtain

$${V}_{t} = \frac{{ℏω}_{g}}{q} \frac{{T}_{2} - {T}_{1}}{{T}_{2}} . \qquad ( A21 )$$

For a cooling device, the standard metric for its efficiency is the cooling coefficient of performance (COP) defined as

$$COP = \frac{P}{JV} , \qquad ( A22 )$$

where P (in Eq. A13) measures the net outflow of heat from the cold body, and JV is the injected electric power into body 1. Substituting Eqs. A18 and A19 into Eq. A22 results in

$$COP = \frac{( {e}^{\frac{qV}{{k}_{B} {T}_{1}}} {F}_{1 \to 2}^{0} - {F}_{2 \to 1}^{0} ) ( {ℏω}_{g} - qV )}{( {e}^{\frac{qV}{{k}_{B} {T}_{1}}} {F}_{1 \to 2}^{0} - {F}_{2 \to 1}^{0} ) qV} = \frac{{ℏω}_{g}}{qV} - 1. \qquad ( A23 )$$

According to the Second Law of Thermodynamics, the COP should be bounded by the Carnot limit, i.e.

$$COP \leq \frac{{T}_{1}}{{T}_{2} - {T}_{1}} . \qquad ( A 24 )$$

From Eqs. A21 and A23, we see that the COP reaches the Carnot limit at V=Vₜ, and falls below the Carnot limit when V>Vₜ. At the Carnot limit, the net cooling power density approaches zero. Thus, for most practical applications one would not operate at the Carnot limit even if the device is capable of achieving this limit.

### A3.2) Analytical Model for Heteromaterial Structure

The simple analytical model in Section A3.1 for the homomaterial structure can be straightforwardly generalized to the heteromaterial structure where the two semiconductors have different band gaps. Without loss of generality, we assume that the two semiconductors have band gap frequencies ω_{g1} and ω_{g2}, respectively, with ω_{g1}>ω_{g2}. The thermal exchange between the semiconductors will only occur in the frequency range above ω_{g1}. Thus, from the results in Section A3.1, we can replace ω_{g} by ω_{g1} to obtain the corresponding results for the heteromaterial case, which reaches the Carnot limit at V=Vₜ as well.

For cooling purposes, the semiconductor on the cold side should have a band gap that is larger as compared to the semiconductor on the hot side to ensure that all the emission from the cold side can be absorbed by the hot side.

### A3.3) Numerical Results

To directly check the analytical model, we performed exact calculations based on fluctuational electrodynamics. We consider the configuration in FIG. 3 and set the temperatures for the hot and cold bodies to be T₁=290K and T₂=300 K, respectively. In the calculations, we use the formalism discussed in Section A2, except that we set E_{1→2}^{p}=E_{1→2}^{p}=0 and R=0, i.e. we ignore contributions from phonon-polariton excitations and non-radiative recombination.

We perform these exact calculations for both the homomaterial and heteromaterial structures. In the homomaterial case, we choose InAs as the semiconductor for both bodies. On the hot side (body 2), we set t₂=4 μm to ensure that it has significant absorption for our wavelengths of operation. On the cold side (body 1), we choose a thickness to be t₁=1 μm to facilitate the comparison with the non-ideal case as discussed in the next section. In the heteromaterial case, we choose InSb for the hot body and InAs for the cold body. In our calculations, the data for ∈ₑ(ω,0) and ∈ₚ(ω) for InAs and InSb are obtained from the literature. Eq. A2 is then used to determine the appropriate above-bandgap dielectric function in Eq. A4 when a non-zero voltage is applied. In Eq. A6, we choose [symbol] ω_{g}=0.31 eV, below which the contribution to photo emission from inter-band processes for InAs is negligible.

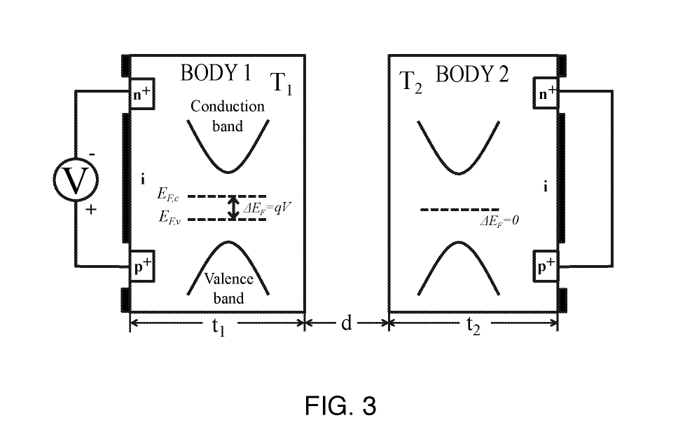

We consider the homomaterial case first. The top row of FIG. 4 contains plots of P_{ideal} as a function of V of (a) the homomaterial and (b) the heteromaterial structures for different d (indicated in the legend). The horizontal dashed lines in (a) and (b) represent the zero power densities. The bottom row of FIG. 4 shows the corresponding COP as a function of V of (c) the homomaterial and (d) the heteromaterial structures (assuming no non-idealities) for the same values of d as in (a) and (b). The decreasing dashed curves in (c) and (d) are obtained from Eq. A23. The horizontal dashed lines in (c) and (d) represent the Carnot efficiency limit. Vₜ in (c) and (d) indicates the threshold voltage.

Part (a) of FIG. 4 shows the net outflow power density P_{ideal} as a function of the external bias V for various gap separations d. For every d at V=0, there is net power flow from the hot body (body 2) to the cold body (body 1) and P<0, as expected. As V increases, the outflow from body 1 also increases. As V increases beyond a threshold voltage Vₜ, P becomes positive and body 1 experiences a net outflow of energy and hence cooling. For this system, Eq. A21 gives a Vₜ of 0.0122V, which agrees quite well with the Vₜ=0.0129V obtained from the exact calculations. At a large V, the net power density P increases approximately exponentially as a function of V, in agreement with Eq. A19. For a fixed V, the power density increases significantly as one reduces d This effect is typical of near-field heat transfer where the transferred power increases as the separation d between the two bodies decreases.

For the homomaterial structure, the numerically obtained COP as a function of V is plotted in part (c) of FIG. 4 for several separations d, and compared to the analytical model of Eq. A23. The analytical model predicts that in the ideal case, the COP should be independent of the separation d as confirmed by the numerical simulations. The only significant deviation from the analytic model occurs near Vₜ. In particular, the analytic model predicts a discontinuity in COP at Vₜ, while the exact numerical results show a zero COP at Vₜ followed by a rapid increase of the COP towards the Carnot limit at a voltage slightly above Vₜ. The discrepancies here arise since the photon flux rate and the net photon energy transfer rate vanish at slightly different voltages in the exact calculation at Vₜ. As a result, the analytic model becomes inaccurate at V near Vₜ. The exact numerical results show that our structure can indeed have a cooling performance close to the Carnot limit in the absence of non-idealities.

The numerically obtained power density and COP behaviors for the heteromaterial structure are shown in parts (b) and (d) of FIG. 4, respectively. The behaviors are almost identical to that of the homomaterial case, confirming the analysis presented in Section A3.2.

### A4) Effects of Non-Idealities

### A4.1) Numerical Results

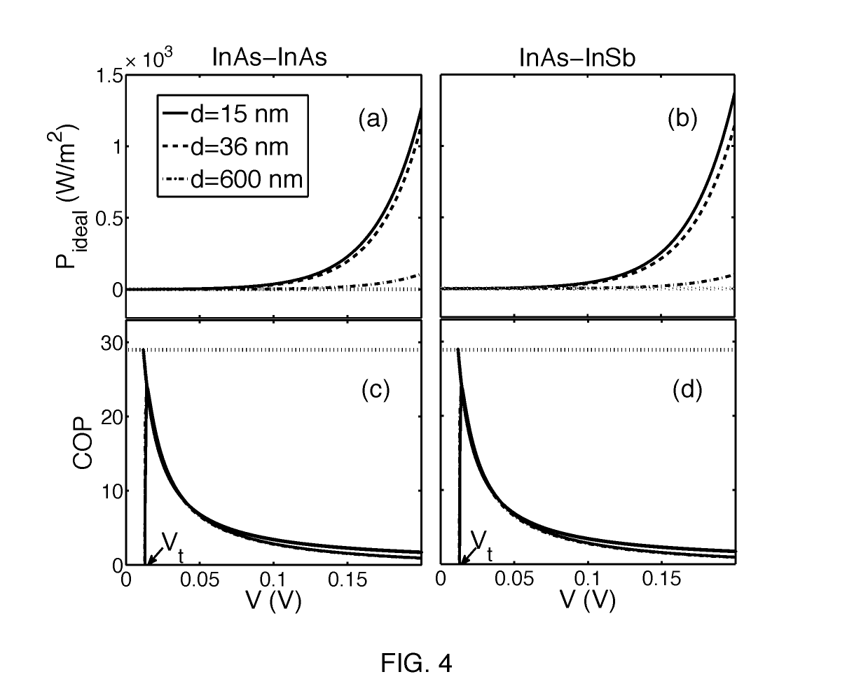

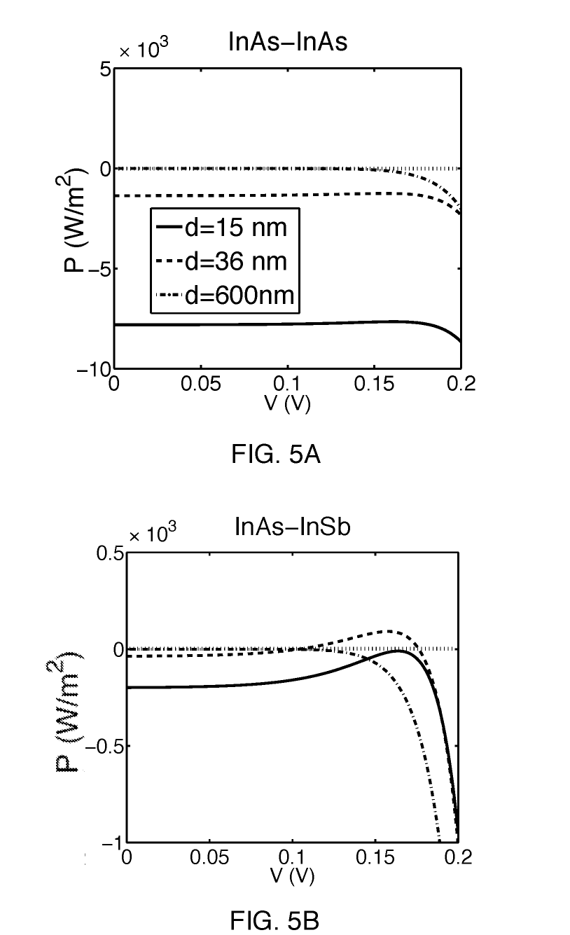

In the previous section we showed that in the absence of non-idealities, the configuration shown in FIG. 3 can operate as an ideal cooling device with efficiency approaching the Carnot limit. In this section we consider the effects of the two non-idealities that are intrinsic to the III-V semiconductors used in the configuration of FIG. 3: (1) the Auger recombination process, the dominant non-radiative recombination processes for high quality material, and (2) phonon-polariton heat transfer, which results in heat flow from the hot body to the cold body that is independent of the electronic transitions and therefore the applied voltage on body 1. The numerical results for the power density P including these two effects are shown in FIGS. 5A and 5B for the homomaterial structure of InAs and the heteromaterial structure including InAs and InSb, respectively. The gray dashed line in FIG. 5B indicates the zero power density. Unlike the ideal scenario without non-idealities ((a) and (b) on FIG. 4), where the homomaterial structure and the heteromaterial structure show identical behaviors, here the two structures behave very differently. For the homomaterial case, there is no longer any net cooling for any separation d and at any voltage. For the heteromaterial case, there is also no net cooling at the large and small d limits. On the other hand, for the heteromaterial structure with a separation d=36 nm, for example, net cooling can still be achieved with a peak cooling power density of 91.23 W/m² at 0.158V of forward bias on body 1.

In the subsequent sections, we elucidate the effects of non-idealities that lead to the behaviors shown in FIGS. 5A-B. We discuss the effects of Auger recombination in Section A4.2. The effects of phonon-polariton heat transfer are then considered in Section A4.3. Finally, the performance including both non-idealities is shown in Section A4.4.

### A4.2) Effects of Auger Recombination

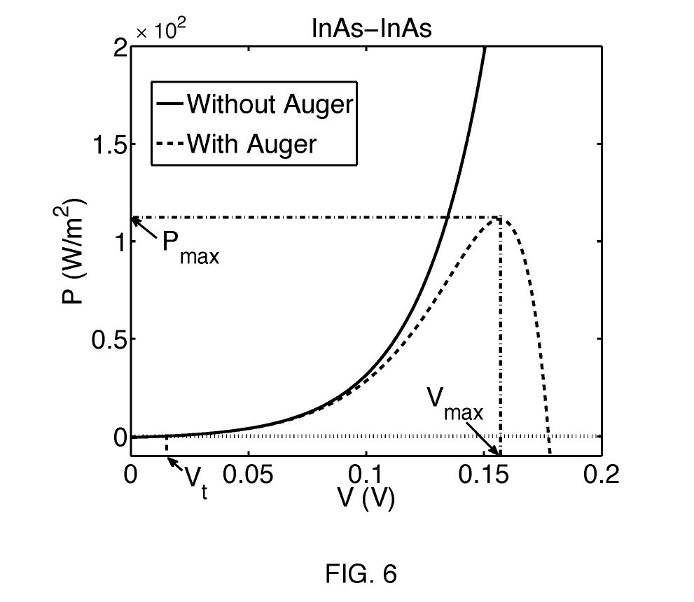

To illustrate the effect of Auger recombination, we consider the same configurations as shown in FIG. 3 but now with the effect of Auger recombination included. For simplicity, we do not include the contribution from phonon-polariton heat transfer in this section. In the following, we first consider a homogeneous InAs—InAs structure with separation d=36 nm. FIG. 6 plots this example structure's net output power density crossing the vacuum gap as a function of voltage for the cases with and without Auger recombination. We observe from FIG. 6 that for voltages below Vₜ, the two power density curves almost overlap with one another. This similarity in power density is expected since the effect of Auger recombination is sufficiently weak when the applied voltage is small.

However, as V increases beyond Vₜ in FIG. 6, the net outflow power density reaches a maximum for the case with Auger recombination. For the case with Auger recombination, the peak power density is denoted as Pₘₐₓ=111.31 W/m² with an associated voltage Vₘₐₓ=0.156V. The threshold voltage for body 1 to reach net cooling is labelled Vₜ (0.013V), and the zero power density level is denoted by the horizontal dashed line.

We can explain this behavior as follows: The semiconductor's carrier density increases significantly as the applied voltage increases beyond Vₜ. Furthermore, since the Auger recombination rate in Eq. A12 scales with a higher exponent with respect to carrier density as compared to radiative recombination rate, the non-radiative recombination rate (R in Eq. A11) increases faster and eventually dominates over the radiative recombination rate. The Auger recombination process generates heat inside body 1. As a result, the net outflow power density from it reaches a maximum as V increases. Therefore in the presence of Auger recombination, there exists an optimal voltage at which the cooling power is maximized.

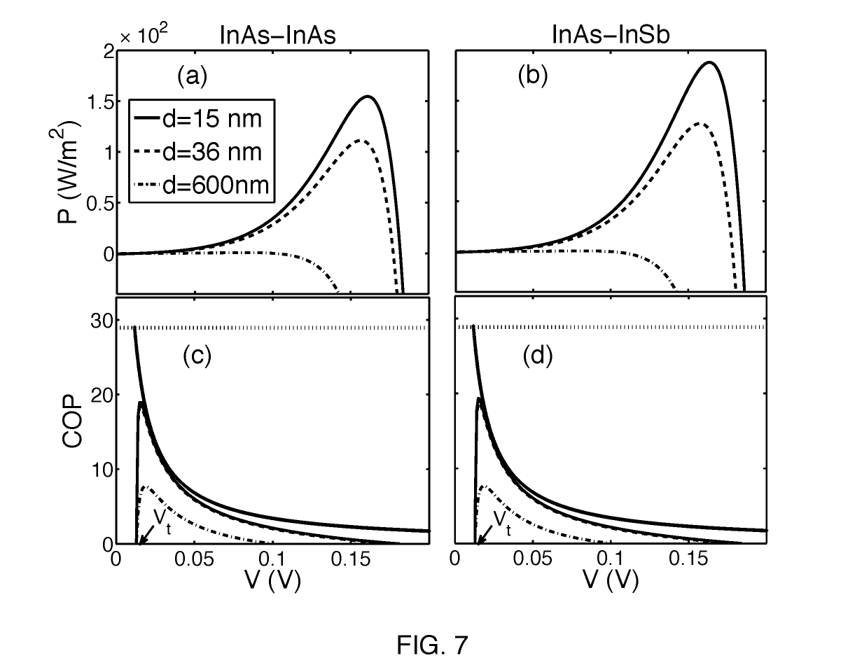

In FIG. 7, we plot the cooling power density P and the COP as a function of voltage for both homomaterial and heteromaterial structures with various separations d, taking into account Auger recombination. Here the top row includes plots of power density P as a function of V for (a) the homogeneous and (b) the heterogeneous structures in the presence of Auger recombination. Plots are shown for different separations d [inset of (a)]. (c) and (d) show the COP as a function of V for the same set of d's. The dashed curves in (c) and (d) represent the analytical solution without Auger recombination, as obtained from Eq. A23. The horizontal dashed lines in (c) and (d) represent the Carnot efficiency limit for this configuration.

The homomaterial and heteromaterial structures show qualitatively similar behaviors. At d=600 nm, there is only small net cooling of approximately 0.76 W/m² for both junctions. Significant cooling is observed for smaller d. For each d, the cooling power density shows a maximum at a specific voltage Vₘₐₓ, a behavior that was already discussed in FIG. 6 for d=36 nm. Moreover, Vₘₐₓ increases as we reduce d. The reduction of d results in an increase of the radiative recombination rate. Hence the system can operate at a higher voltage before the non-radiative recombination process dominates. We also observe an increase of maximum power density as we reduce d. This arises as a result of both the power transfer enhancement for small d, as well as the higher operating voltage.

Parts (c) and (d) of FIG. 7 show the COP as a function of applied voltage V for the same separations d in both homomaterial and heteromaterial structures. In general, the presence of non-radiative recombination reduces the COP. This reduction, however, is far less severe as we decrease the separation d into the near-field region. This is because the non-radiative recombination rate is independent of d, while the radiative recombination rate increases as we reduce d. Thus, the detrimental effect of non-radiative recombination is mitigated as we reduce d.

We also note that such non-radiative recombination is significant only when a forward bias is applied. Hence in these calculations we do not need to include the Auger recombination on the hot side where no voltage is applied. In the heteromaterial case, this means that we only need to take into account the Auger recombination on the InAs side. In addition, the Auger combination rate per unit area is proportional to the thickness of the structure, as seen in Eq. A12. Thus for the cold side InAs, we have chosen its thickness t₁=1 μm as a compromise between the need to maximize emission and the need to reduce Auger recombination.

### A4.3) Effects of the Phonon-Polariton Heat Transfer

From the discussions above, we see that to mitigate the effect of Auger recombination, one generally prefers to operate in the near-field regime where the separation between the two bodies is small. However, in this near-field regime, the presence of phonon-polariton heat transfer can become very substantial. For a cooling device as in this section, such a phonon-polariton heat transfer represents a detrimental leakage pathway.

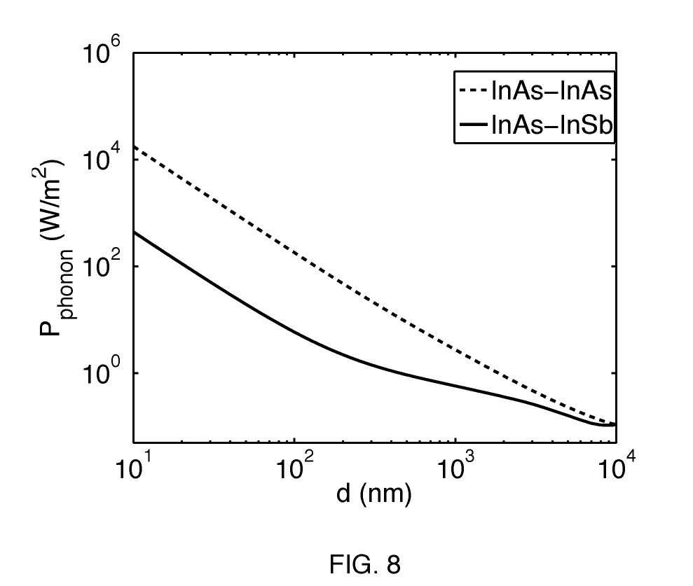

We plot in FIG. 8 the phonon-polariton contribution to the heat transfer Pₚₕₒₙₒₙ as a function of gap separation d for the homomaterial (dashed curve) and heteromaterial (solid curve) structures. At d=10 nm, the phonon-polariton heat transfer in the heteromaterial structure is one order of magnitude lower than that of the homomaterial structure. For the homomaterial case, the heat transfer power increases approximately as 1/d² when d decreases since the two bodies have surface phonon-polariton excitations with near matching frequencies. This behavior is consistent with the literature on near-field heat transfer. The presence of such strong phonon-polariton heat transfer, in combination with the Auger recombination is sufficient to eliminate any cooling effect in the homomaterial structure, as demonstrated in FIG. 5A.

To demonstrate cooling in the presence of non-idealities, one therefore needs to mitigate the effect of phonon-polariton heat transfer. As a straightforward approach, we consider a heteromaterial structure in which the semiconductors are different. For the heteromaterial structure considered in this paper, the surface phonon-polariton excitation frequencies for the InAs-vacuum and InSb-vacuum interfaces no longer match, and hence the phonon-polariton heat transfer is substantially reduced as compared to the homomaterial structure (FIG. 8). The use of such heteromaterial structures in the near-field regime thus allows us to mitigate the detrimental effects of both Auger recombination and phonon-polariton heat transfer, and therefore enables significant cooling as shown in FIG. 5B.

### A4.4) Performance Including Both Non-Idealities

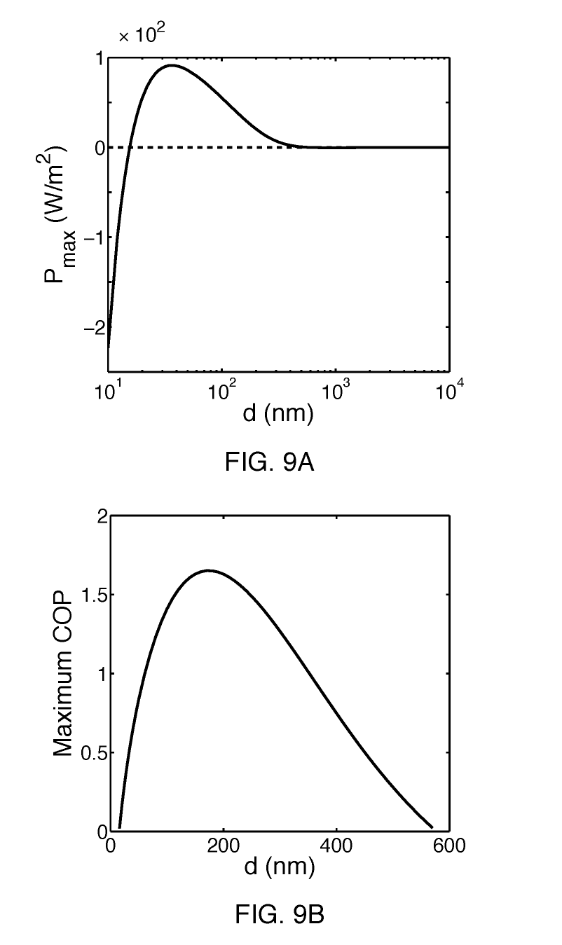

FIG. 9A shows the peak outflow power density Pₘₐₓ versus separation d in the presence of Auger recombination and phonon-polariton heat transfer for the heteromaterial InAs—InSb structure. At separations d<16 nm, the surface phonon-polariton heat transfer dominates over above-bandgap photon heat transfer and the peak power density is negative, indicating there is a net energy flow from the hot side to cold side and hence the absence of any cooling effect. Whereas for large separations d<570 nm, Auger recombination dominates and we also do not observe any net cooling for body 1. In the intermediate range from 16 nm to 570 nm, the system can operate as a solid-state cooling device. The largest cooling power density is found when d=36 nm, for which V=0.158V yields 91.23 W/m² of cooling power density against the assumed 10K temperature difference. In addition, we note that when the two bodies are near thermal equilibrium, the maximum cooling power density in the near field is three orders of magnitude higher than that in the far field.

FIG. 9B shows the maximum COP achievable for InAs—InSb structures with separations 16 nm, <d<570 nm. The maximum COP is 1.65 and is found at d=170 nm.

Such a COP is comparable to that of thermoelectric coolers at similar operating temperatures in practice, and is significantly higher than other photon-based solid-state cooling schemes, including laser cooling of solids. Therefore, the results here show that the device in FIG. 3 can in principle be used as a high-efficiency solid-state cooling device, even in the presence of significant non-radiative recombination and phonon-polariton heat transfer. In addition, by using quantum wells to mitigate Auger recombination and engineering surfaces to reduce the phonon-polariton coupling, higher COP and cooling power density are achievable by our design.

### A5) Conclusion

In summary, we have shown that controlling the chemical potential of a thermally emissive body could enable significant new opportunities to exploit near-field electromagnetic heat transfer. These include the capability for electronic control of both the magnitude and the direction of heat flow in nano-scale systems and as well as the potential for a solid-state cooling device that operates near the Carnot limit. The cooling effect persists even in the presence of non-idealities such as Auger recombination and phonon-polariton heat transfer. We have further seen that to achieve this, we must place the semiconductor heat absorber in the near field of the electrically driven emitter to mitigate the effect of Auger recombination, and choose a heteromaterial configuration that minimized the parasitic phonon-polariton heat transfer in the near field.

### B) Negative Luminescence

### B1) Introduction

When a semiconductor is under external bias, the expectation value of photon energy per mode above bandgap satisfies the Bose-Einstein distribution

$$θ ( ω , T , V ) = \frac{ℏ ω}{{e}^{\frac{ℏ ω - gV}{{k}_{B} T}} - 1} \qquad ( B 1 )$$

where [symbol] is the reduced Planck's constant, ω is the angular frequency, q is the magnitude of electron's charge, V is the external bias, k_{B} is the Boltzmann constant and T is the temperature of the semiconductor. Thus, in the presence of a negative bias (i.e. V<0), the semiconductor emits less photons as compared to the same system at thermal equilibrium with V=0. In such a situation, as far as thermal radiation properties are concerned, one can equivalently describe the semiconductor as having an apparent temperature lower than its real temperature. This effect, i.e. the suppression of thermal radiation from a semiconductor by applying a negative bias, is commonly referred to as “negative luminescence”, and has applications such as cold shields for IR detectors, radiometric reference sources and dynamic infrared scene projectors.

One potential application of negative luminescence is in the area of solid-state cooling. The case of two semiconductor objects having different temperatures undergoing radiative thermal exchange between them has been considered in the literature, and a net heat flow from the cold to the hot object is possible when the hot object is under a negative bias. In the far-field case in which the separation between the two bodies are much greater than all wavelengths relevant to electromagnetic heat transfer between the bodies, the achievable power density for cooling is fundamentally limited by the Stefan-Boltzmann's law.

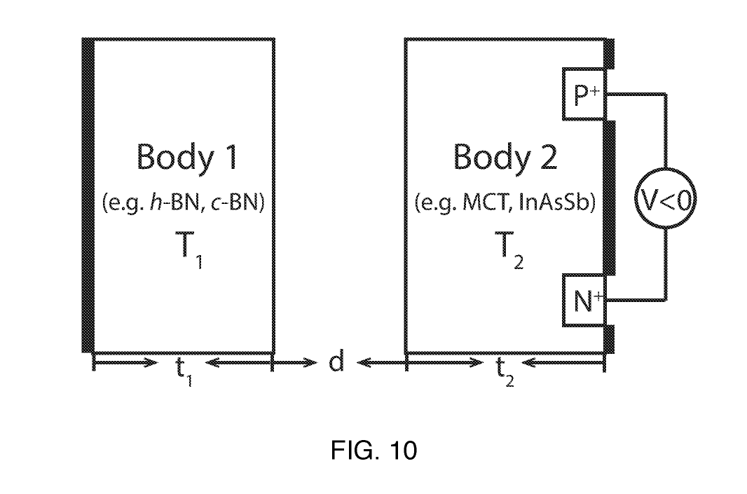

In recent years there have been significant theoretical and experimental efforts in exploring near-field heat transfer, through which the power density can far exceed the far-field limit. Motivated by these efforts, in this section we examine the concept of negative luminescent refrigeration in the near-field regime. We consider a configuration as shown in FIG. 10, where a narrow-bandgap semiconductor under negative bias is placed in close proximity to a dielectric material supporting phonon-polariton resonances, and show that operation in the near-field regime results in significant enhancement of both the power density and coefficient of performance for negative luminescent refrigeration. More specifically, the system of this example includes body 1 (material supporting surface phonon-polaritons, such as hexagonal BN (h-BN) and cubic BN (c-BN)) and body 2 (a narrow-bandgap semiconductor such as HgCdTe (MCT) and InAsSb) in close proximity. The two bodies are backed by perfect electric conductor mirrors. Body 2 is under a negative bias V.

The rest of this section is organized as follows: In Section B2 we briefly review the concept of negative luminescent refrigeration. In Section B3 we present the results of a system including Mercury Cadmium Telluride (MCT) and hexagonal Boron Nitride (h-BN). We conclude in Section B4.

### B2) Brief Review of Negative Luminescent Refrigeration

We start by a brief review of the concept of negative luminescent refrigeration. We consider the configuration shown in FIG. 10, where body 1 at T₁ is in thermal exchange with body 2 at temperature T₂. Body 2 is made of semiconductor with band gap energy E_{g}. We assume that T₁<T₂. The objective of negative luminescent refrigeration is to extract heat from body 1, in spite of the fact that it has a lower temperature, by applying a negative bias V to the semiconductor body 2. We assume the semiconductor region is intrinsic, and external bias is applied through two heavily doped regions labeled P⁺ and N⁺, respectively. The convention for the signs is chosen such that a positive current corresponds to the flow of positive charge from P⁺ anode through the intrinsic region to the N⁺ cathode. The negative bias then generates a negative current I. The total electric power that is used to drive the two-body system is then IV.

A cooling device as such is characterized by its cooling power density and its efficiency. The cooling power density P is defined as the net electromagnetic power per unit area that flows from body 1 to 2. The efficiency of a device is characterized by the coefficient of performance (COP), defined as

$$COP = \frac{P \cdot Area}{IV} = \frac{P}{JV} , \qquad ( B 2 )$$

where J=I/Area with the area being the surface area of body 1 facing body 2.

We now present a simple analytical calculation of the negative luminescent device that highlights the essential physics. Using Eq. B1, and assuming that the heat exchange between the two bodies is narrow-banded near the band gap frequency ω_{g}=E_{g}/ [symbol] , we can then define an apparent radiant temperature T₂* by setting

$$\frac{ℏ {ω}_{g}}{{e}^{\frac{ℏ {ω}_{g} - g V}{{k}_{B} {T}_{2}} - 1}} = \frac{ℏ {ω}_{g}}{{e}^{\frac{ℏ {ω}_{g}}{{k}_{B} {T}_{2}^{*}} - 1}} , \qquad ( B 3 )$$

and hence

$${T}_{2}^{*} = {{T}_{2} ( 1 - \frac{q V}{ℏ {ω}_{g}} )}^{- 1} \qquad ( B 4 )$$

As far as the radiation properties are concerned, the semiconductor has an effective temperature T₂⁺ less than its thermodynamic temperature T₂ in the presence of a negative bias V<0.

In order to achieve solid-state cooling of body 1, we must have T₂*<T₁, and therefore the applied voltage must satisfy V<Vₜ, where the threshold voltage

$${V}_{t} = \frac{ℏ {ω}_{g}}{q} \frac{{T}_{1} - {T}_{2}}{{T}_{1}} , \qquad ( B 5 )$$

In the case of a substantial negative bias, the emission from the semiconductor body 2 can be ignored. Within the same narrow-banded approximation as discussed above, the cooling power density can then be estimated as

Pₘₐₓ= [symbol] ω_{g}F_{1→2}, (B6)

where F_{1→2} is the photon number flux from body 1 to body 2. Also, J=−qF_{1→2}. Therefore, for V<Vₜ, the COP in Eq. B2 is simplified to be

$$COP = - \frac{ℏ {ω}_{g}}{q V} . \qquad ( B7 )$$

According to the second law of thermodynamics, the COP should be bounded by the Carnot limit, i.e.

$$COP \leq \frac{{T}_{1}}{{T}_{2} - {T}_{1}} . \qquad ( B 8 )$$

From Eqs. B5 and B7, we see that the COP reaches the Carnot limit exactly when V=Vₜ, and falls below the Carnot limit when V<Vₜ.

We now illustrate the choice of materials and the operation regime for the device using the simple analytic model. In general, the photon flux from body 1 to body 2 is

$${F}_{1 \to 2} = {\int }_{{ω}_{g}}^{+ ∞} d ω A ( ω ) \frac{1}{{e}^{ℏ ω \text{/} {k}_{B} {T}_{1}} - 1} , \qquad ( B 9 )$$

where

$$A ( ω ) = {A}_{0} ( ω ) = \frac{{ω}_{2}}{4 {π}^{2} {c}^{2}}$$

if the two bodies are in the far field, the body 1 is a blackbody and the absorption coefficient of body 2 is unity at frequencies above the band gap. A(ω) could be greater than A₀(ω) in the near-field case. In both near-field and far-field cases, suppose [symbol] ω>>k_{B}T₁, Eq. B9 is approximated as

F_{1→2}=∫_{ω}_{_{g}}^{+∞}dωA(ω)e⁻ [symbol] ^{ωk}^{_{B}}^{T}^{₁}∂e⁻ [symbol] ^{ωg/k}^{_{B}}^{T}^{₁}, (B10)

Therefore in this case, the cooling power density is exponentially suppressed by the factor e⁻ [symbol] ^{ωg/k}^{_{B}}^{T}^{₁}. It follows that to have substantial cooling power density, we would like to choose a narrow-bandgap semiconductor with hω_{g} on the order of k_{B}T₁. For operation around the room temperature 300K, the use of narrow-bandgap semiconductor is therefore preferred.

In Eq. B9, in the far-field regime, for a general body 1 different from a black body, we always have A(ω)<A₀(ω). Therefore, in the far-field regime, the cooling power density is limited by the Stefan-Boltzmann limit of blackbody radiation. On the other hand, since in the near-field the heat exchange can significantly exceed the Stefan-Boltzmann limit, the near-field regime represents an opportunity to significantly enhance the cooling power density achievable with negative luminescence.

### B3) Analysis of a Near-Field Negative Luminescent Refrigeration Device

### B3.1) Material Systems & Geometry

The discussion in Section B2 highlights the essential physics of negative luminescent refrigeration, and points to the importance of performing such cooling in the near-field regime. Motivated by this discussion, here we present a detailed analysis of the system shown in FIG. 10. For the semiconductor (i.e. body 2 in FIG. 10), we use a narrow-bandgap semiconductor Hg₁₋ₓCdₓTe (Mercury Cadmium Telluride, or MCT). MCT is a commonly used material for infrared detector applications. With x=0.2, it has a band gap of E_{g}=0.169 eV. In our calculation, we choose the semiconductor to have a temperature of T₂=300K. The bandgap of MCT therefore equals a few times k_{B}T₂=0.026 eV. The dielectric constant of MCT as a function of frequency is taken from the literature.

For the body to be cooled (i.e. Body 1 in FIG. 10), we assume a temperature T₁=290K, and choose to use hexagonal Boron Nitride (h-BN). h-BN is an anisotropic material with a uniaxial dielectric tensor as characterized by the ordinary and the extraordinary dielectric functions ∈₀ and ∈ₑ, respectively. Both ∈₀ and ∈ₑ have a resonance corresponding to an underlying phonon-polariton resonance. It is well known that the presence of surface phonon-polariton leads to significantly enhanced near-field thermal transfer, hence the choice of h-BN in our case since its phonon-polariton frequency is well aligned with the band gap of MCT, corresponding to the wavelength of 7.3 μm. The phonon-polariton resonant wavelengths, defined as the wavelengths where the imaginary parts of ∈₀ and ∈ₑ maximize, are located at 12.8 μm and 7.3 μm, respectively. The dielectric function of h-BN as a function of frequency is obtained from the literature.

In the calculation, the thicknesses of body 1 and body 2, denoted as t₁ and t₂, are chosen to be 5 μm to ensure significant emission and absorption. The two bodies are separated by a vacuum gap of size d, and both bodies are backed by perfect electric conductor mirrors. We only consider the case where the c-axis of h-BN is perpendicular to the surface of body 1.

### B3.2) Computational Methods

To evaluate the performance of the negative luminescent refrigeration device, we use the formalism of fluctuational electrodynamics. In this formalism, one describes the heat transfer between objects by computing the electromagnetic flux resulting from fluctuating current sources inside each object. The cooling power density can then be obtained as

P=P_{ideal}=∫_{ω}_{_{g}}^{+∞}[θ(ω,T₁,0)−θ(ω,T₂,V)]Φ(ω)dω. (B11)

In Eq. B11, Φ(ω) is the sum of transmission factors at lateral wave vector k_{∥} at frequency ω, i.e.

$$Φ ( ω ) = \frac{1}{2 π} {\sum }_{j = s , p} \{ {\int }_{0}^{{k}_{0}} \frac{{d}^{2} {k}_{‖}}{4 {π}^{2}} \frac{( 1 - {\vert {r}_{j}^{( 1 )} \vert}^{2} ) ( 1 - {\vert {r}_{j}^{( 2 )} \vert}^{2} )}{{\vert 1 - {r}_{j}^{( 1 )} {r}_{j}^{( 2 )} {e}^{2 i {k}_{1} d} \vert}^{2}} + {\int }_{{k}_{0}}^{∞} \frac{{d}^{2} {k}_{‖}}{4 {π}^{2}} \frac{4 Im ( {r}_{j}^{( 1 )} ) Im ( {r}_{j}^{( 2 )} )}{{\vert 1 - {r}_{j}^{( 1 )} {r}_{j}^{( 2 )} {e}^{2 i {k}_{1} d} \vert}^{2}} \} \qquad ( B 12 )$$

where k₀=ω/c is the free space wave vector, k_{∥}=(kₓ,k_{y}), k_{⊥}=\sqrt{k₀²−|k_{|}²|} is the wave vector perpendicular the surfaces of body 1 and 2, j=s,p accounts for the s and p polarizations, rⱼ⁽¹⁾ and rⱼ⁽²⁾ are Fresnel reflection coefficients from vacuum to body 1 with PEC and from vacuum to body 2 with PEC for j polarization, respectively.

A semiconductor that is ideal for negative luminescent refrigeration should have its entire emission arising from electron-hole recombination. An ideal semiconductor therefore should have emission only at frequencies above the band gap frequency. Moreover, the recombination should be completely radiative. In the ideal case, the current density J_{ideal} is

$$J = {J}_{ideal} = q {\int }_{{ω}_{g}}^{+ ∞} [ \frac{θ ( ω , {T}_{2} , V )}{ℏ ω} - \frac{θ ( ω , {T}_{1} , 0 )}{ℏ ω} ] Φ ( ω ) d ω , \qquad ( B 13 )$$

from which the COP can then be obtained using Eq. B2.

In the scheme as considered here, the inherent material non-idealities are the existence of significant non-radiative recombination, such as Auger recombination, as well as sub-bandgap thermal radiation. In the presence of non-radiative recombination, the total current density now has contributions from both radiative and non-radiative recombination, i.e.

J=q(J_{ideal}+R). (B14)

where R is the non-radiative recombination rate per unit surface area, and then COP can be obtained by combining Eqs. B2 and B14.

The net sub-bandgap heat flow is from the hot body 2 to the cold body 1, and therefore represents a parasitic process that is detrimental for the objective of cooling here. In the presence of free carrier thermal radiation, the net sub-bandgap heat flow from body 2 to body 1 is expressed as

P_{S}=∫₀^{Ωg}[θ(ω,T₂,0)−θ(ω,T₁,0)]Φ(ω,V)dω. (B15)

Here since the density of free carriers of the semiconductor depends on the voltage, the dielectric function of the semiconductor in the sub-band gap wavelength range thus also depends on the voltage. Φ(ω,V) is computed with a voltage correction included. The overall net cooling power density is

P=P_{ideal}−P_{S} (B16)

and the COP can be obtained by combining Eqs. B2, B14 and B16.

The objectives of our calculation here are to illustrate the theoretical limit of the performance using the ideal case, and to consider the impact of the most fundamental non-idealities on the performance of the device. In the following, we first discuss the ideal case in Section B3.3. We then discuss non-radiative recombination and sub-bandgap radiation in Section B3.4 and B3.5, respectively.

### B3.3) Ideal Case

We consider the ideal case first. In the absence of non-radiative recombination and sub-bandgap free carrier thermal radiation, we use Eqs. B11 and B13 to compute the cooling power P and the current density J, respectively and then obtain the COP with Eq. B2.

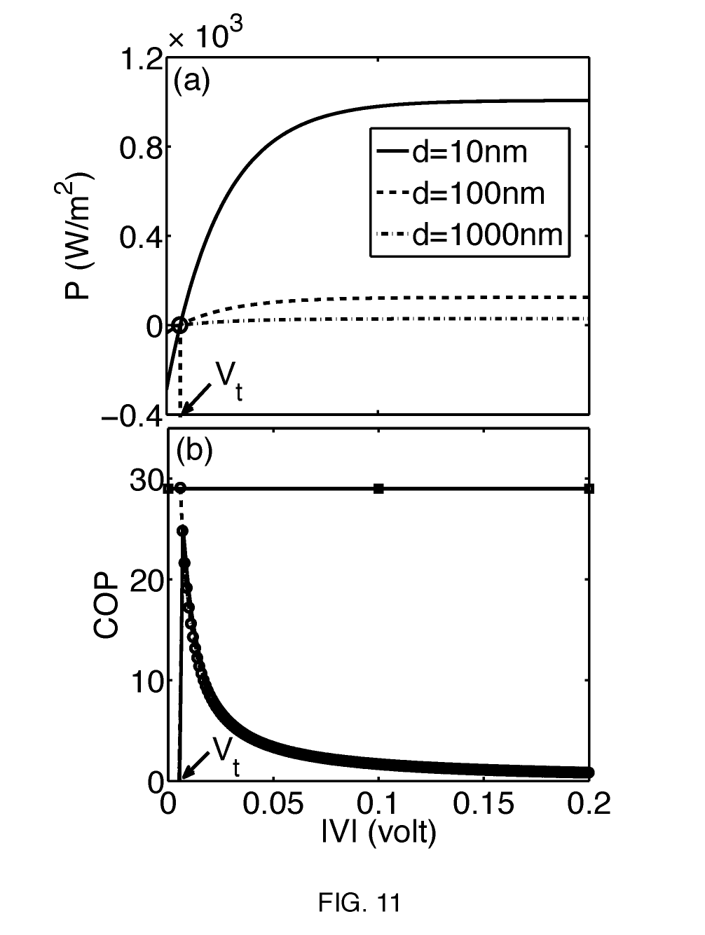

The net cooling power densities P as a function of the magnitude of the bias for d=10, 100, 1000 nm are shown in part (a) of FIG. 11. For each d, when V=0, the temperature difference between the bodies results in net heat flow from body 2 to body 1 and thus a negative value of P. Applying a negative voltage to body 2, i.e. having a negative V, results in the suppression of the radiation from body 2 and hence the increase of the cooling power density P. When V<Vₜ, the apparent temperature of body 2 becomes lower than that of body 1, and thus P becomes positive. As indicated in FIG. 11, in the ideal case considered here this threshold voltage Vₜ is independent of the gap size d. The value of Vₜ=−0.0065V, as obtained from simulation, compares reasonably well with the prediction of Vₜ=−0.0058V as obtained from the results of the simple analytical model described in Eq. B5. When the magnitude of V is sufficiently large, the heat flux from body 2 to 1 becomes negligible for the temperatures considered here and therefore P saturates to the heat flux from body 1 to 2. As d decreases from 1000 nm to 10 nm, the maximum cooling power density increases from 29.3 W/m² to 1007.0 W/m². As a comparison, the maximum power density in the far-field limit for this system is 11.5 W/m². Operating in the near-field regime therefore significantly increases the cooling power density beyond the far-field limit.

In part (b) of FIG. 11, we show the COP for the three gap separations. For all gap sizes, at V=Vₜ the COP is zero as expected since the net cooling power density is zero. As V decreases below Vₜ, the COP quickly maximizes as then decreases as V further decreases. The COP is largely independent of the gap size. Except for the regime near Vₜ, the COP agrees very well with the analytical model results of Eq. B7, shown here by a dashed line. For d=10 nm, the maximum COP is 25.3, which can be compared with the Carnot efficiency limit of 29 for this system. In this ideal case, the device can operate with very high efficiency.

The result in this section shows that in the absence of material non-idealities, the device shown in FIG. 10 can perform with a high COP close to the Carnot limit, as well as a high cooling power density far exceeding the far-field limit by operating in the near field. In what follows, we evaluate how the inherent non-idealities of the semiconductor influence the device performance.

B3.4) Auger Recombination

The analysis in Section B3.3 assumes that the only carrier generation or recombination mechanism in the semiconductor is completely radiative. On the other hand, for narrow-band gap semiconductors such as MCT, there is significant Auger recombination which is non-radiative. In this section, we evaluate the impact of Auger processes. The rate of net Auger recombination R in Eq. B14 takes the form

$$R = {C}_{0} {n}_{1}^{3} [ exp ( \frac{3 q V}{2 {k}_{B} T} ) - 1 ] {t}_{2} , \qquad ( B 17 )$$

where C₀ is the Auger recombination coefficient, nᵢ is the intrinsic carrier density and t₂ is the thickness of the semiconductor. For MCT, nᵢ=2.614×10¹⁶ cm⁻³ and C₀=4.88×10⁻²⁶ m⁶·s⁻¹. The first and second term in the bracket of Eq. B17 arise from recombination and generation processes, respectively.

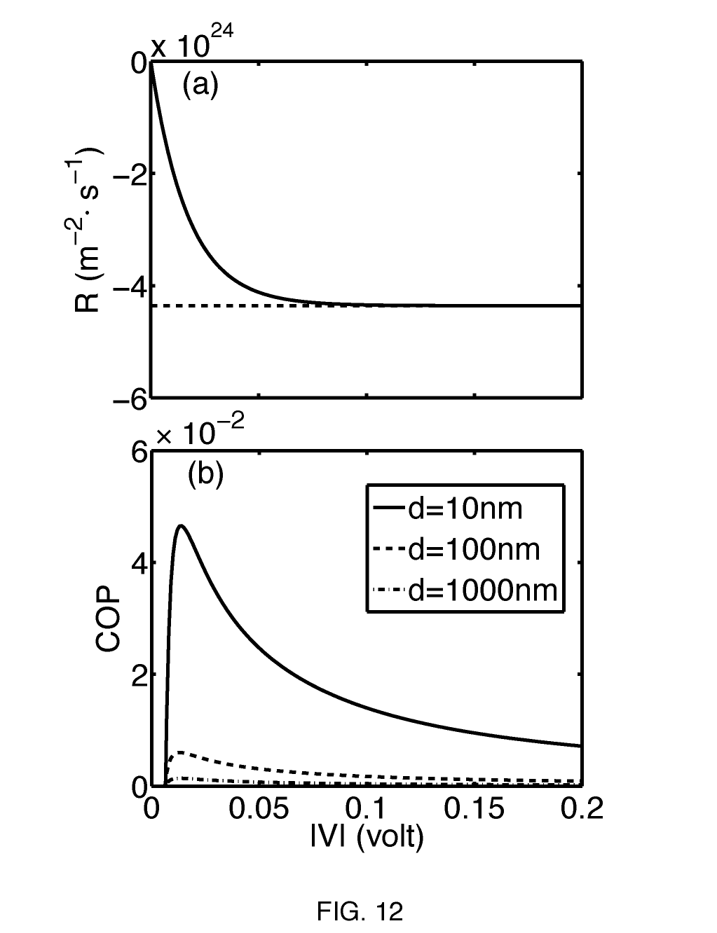

Part (a) of FIG. 12 shows the net Auger recombination rate R as a function of the magnitude of the reverse bias. The generation rate is plotted with a black dashed line. At V=0, the semiconductor is at equilibrium and the net Auger recombination rate is zero since the generation rate balances the recombination rate as shown in Eq. B17. With a large enough negative bias, the net recombination rate saturates to a large negative value. In such a case, the application of large negative bias suppresses the carrier density and hence suppresses carrier recombination. As a result, there is a net generation of carriers in the system, which is represented by a net negative recombination rate.

The presence of Auger recombination does not affect the cooling power since it occurs in body 2. This can be seen from the formalism in Section B3.2. On the other hand, the cooling power at large negative voltages is given by the radiation from body 1 to body 2. Therefore, the cooling power is the same as in part (a) of FIG. 11 even in the presence of Auger generation given that the temperature of body 2 is maintained constant.

Auger recombination, on the other hand, significantly degrades the COP. We compute the COP using Eqs. B2, B11 and B14. Part (b) of FIG. 12 shows the COP as a function of the magnitude of voltage for d=10, 100, 1000 nm in solid, dashed and dotted curves, respectively. Comparing part (b) of FIG. 12 with part (b) of FIG. 11, we see that the COP is degraded by several orders of magnitude as compared to the ideal case. In this case, the COP increases in the near field, since operating in the near field enhances radiative recombination and hence enhances internal quantum efficiency for the radiative processes in body 2.

### B3.5) Sub-Bandgap Thermal Radiation

For a narrow-bandgap semiconductor with high intrinsic carrier density, the free carrier can result in a large thermal emission in the sub-bandgap wavelength regime. Such sub-band gap heat transfer is detrimental since it results in a heat flow from the hot to the cold bodies. On the other hand, the free-carrier density can be suppressed using negative bias. In this section we discuss the sub-bandgap heat transfer at long wavelengths.

To model the free-carrier absorption, for simplicity, in the frequency range below the bandgap of MCT we assume a Drude dielectric function

$$ε ( ω ) = 1 - \frac{{N}_{e} {q}^{2} \text{/} {ε}_{0} {m}_{e}^{*}}{{ω}^{2} + i ω {γ}_{e}} - \frac{{N}_{h} {q}^{2} \text{/} {ε}_{0} {m}_{h}^{*}}{{ω}^{2} + i ω {γ}_{h}} \qquad ( B 18 )$$

where Nₑ (Nₕ) and mₑ* (mₕ*) are the concentration and the effective mass of electrons (holes), respectively, γₑ(γₕ) is the damping rate of the electron (hole) plasma oscillation, and ∈₀ is the vacuum permittivity. For MCT with x≈0.2, mₑ*=0.0114m₀,mₕ*=0.55m₀, where m₀ is the electron mass. γₑ and γₕ are related to the mobilities of electrons (μₑ) and holes (μₕ) through γₑ=q/mₑ*μₑ, γₕ=q/mₕ*μₕ, where μₑ=1.0×10⁴ cm²/V·s, μₕ=100×10⁴ cm²/V·s. In the presence of a bias V, Nₑ and Nₕ scale exponentially as a function of V, expressed as

$${N}_{e} = {N}_{h} = {n}_{i} exp ( \frac{q V}{2 {k}_{B} T} ) .$$

We also assume the mobilities are independent of V. For h-BN, here we again use the dielectric function model from the literature.

In evaluating the integral of Eq. B15 which is used for calculating the sub-bandgap heat transfer, instead of integrating in frequency from 0 to ω_{g}, we integrate between a narrower frequency range from 177×10¹³s⁻¹ to 2.13×10¹⁴s⁻¹, corresponding to the wavelengths range between 50 μm and 8.86 μm. This is sufficient to capture most of the contributions to sub-band gap heat exchange while reducing the computational cost. Having obtained the sub-band gap heat transfer, the cooling power is then obtained from Eq. B16. In the section here we also take into account Auger recombination by using Eq. B14 to compute the current density. From this the COP is then computed using Eq. B2.

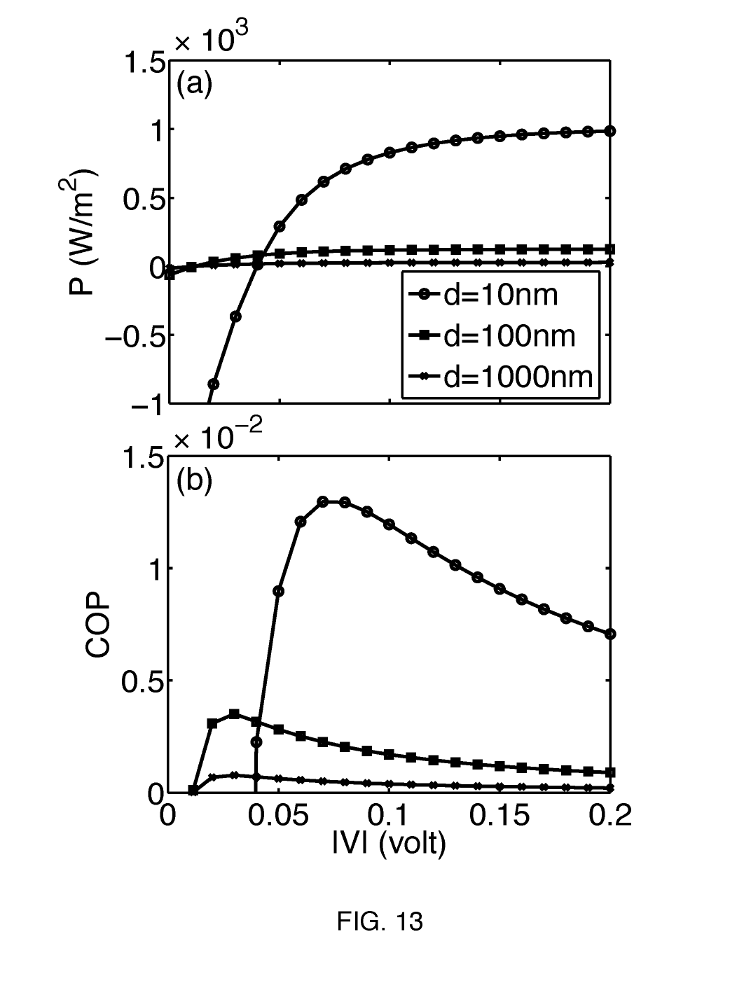

We shown the net cooling power density as a function of the magnitude of the reverse bias for d=10, 100, 1000 nm in part (a) of FIG. 13 in solid, dashed and dotted curves, respectively. In all three cases, cooling can be achieved with a negative bias having a sufficiently large magnitude. Unlike the ideal case, however, the threshold voltage in this case does depend on the spacing d. As d decreases, the sub-bandgap heat transfer increases faster than that of above-bandgap heat transfer, and therefore a larger reverse bias is needed for the device to reach the threshold condition. At d=10 nm, the net cooling power density can reach 1006.4 W/m² at V=−0.2V. When the magnitude of V is sufficiently large, the free-carrier density is strongly suppressed, and the net cooling power density approaches the ideal case, as can be seen from part (a) of FIG. 13.

In part (b) of FIG. 13, the COP as a function of the magnitude of the voltage for d=10, 100, 1000 nm is shown in solid, dashed and dotted curves, respectively. Compared to part (b) of FIG. 12, since the net cooling power density is degraded by the presence of sub-bandgap heat transfer, the COP is much lower for most of the values of the bias voltage. On the other hand, since the decrease of V results in the suppression of the sub-bandgap heat transfer, when the magnitude of V is sufficiently large, the COP becomes close to that in part (b) of FIG. 12. Therefore, for a large |V|, the COP is limited by the Auger recombination.

To briefly summarize this section, in the scheme for near-field negative luminescent refrigeration as considered here, the cooling power can reach the radiative limit as defined solely by the radiative heat exchange of the two bodies, in spite of Auger recombination and sub-bandgap heat radiation from free carriers that typically occur in narrow-bandgap semiconductors. The COP in this scheme is limited by the Auger recombination, again independent from the sub-band gap heat radiation from the free carriers, since such radiation is suppressed at a negative bias with sufficiently large bias.

### B4) Conclusion

In this section, we describe a negative luminescent refrigeration device based on near-field electromagnetic heat exchange between a semiconductor under reverse bias and a polar material that supports surface phonon-polariton. The power density of this cooling effect is significantly enhanced in the near-field regime. In the ideal case, the device can operate close to the Carnot limit with a large cooling power density around 10³ W/m² at a gap separation of 10 nm. We further discuss the impacts of non-idealites on the performance of the device. In the presence of strong Auger recombination, such high cooling power density persists. Even with sub-bandgap free carrier thermal radiation included, the cooling power density can still be achieved close to its maximum with a sufficiently large reverse bias. The performance and the robustness to non-idealities of this scheme is of importance to solid-state cooling applications.

1. A solid state heat transfer device, the device comprising:
an emitter having an emitter temperature T_{C};
a collector having a collector temperature T_{H}, wherein T_{C}<T_{H};
wherein the emitter comprises a semiconductor structure configured to emit electromagnetic radiation on application of a forward bias;
wherein a near-field radiative heat flow from the emitter to the collector is controlled by the forward bias;
wherein the collector has a surface resonance configured to provide enhanced net heat transfer from the emitter to the collector.

2. The device of claim 1, wherein the emitter comprises an interband emission structure having a band gap, wherein a resonant energy of the surface resonance is less than the band gap of the emitter, and wherein the enhanced net heat transfer comprises a reduced parasitic near-field heat flow from the collector to the emitter.

3. The device of claim 1, wherein the emitter comprises an interband emission structure having a band gap, wherein a resonant energy of the surface resonance is greater than or equal to the band gap of the emitter, and wherein the enhanced net heat transfer comprises enhanced near-field heat flow from the emitter to the collector.

4. The device of claim 1, wherein the emitter comprises a forward biased intersubband structure having a transition energy Eₜ, and wherein the surface resonance of the collector has an energy that matches Eₜ.

5. The device of claim 1, wherein the collector comprises a non-polar material configured to diminish the surface resonance.

6. The device of claim 1, wherein the collector comprises a polar material configured to enhance the surface resonance.

7. The device of claim 1, wherein the collector comprises a nanostructured or microstructured surface configured to enhance the surface resonance.

8. The device of claim 1, wherein the collector comprises a strained structure configured to enhance the surface resonance.

9. The device of claim 1, wherein the surface resonance is selected from the group consisting of: surface plasmons and surface phonon-polaritons.

10. A solid state heat transfer device, the device comprising:
an emitter having an emitter temperature T_{C};
a collector having a collector temperature T_{H}, wherein T_{C}<T_{H};
wherein the collector comprises a semiconductor structure configured to provide enhanced absorption of electromagnetic radiation on application of a reverse bias;
wherein a near-field radiative heat flow from the emitter to the collector is controlled by the reverse bias;
wherein the emitter has a surface resonance configured to provide enhanced net heat transfer from the emitter to the collector.

11. The device of claim 10, wherein the collector comprises an interband emission structure having a band gap, wherein a resonant energy of the surface resonance is less than the band gap of the collector, and wherein the enhanced net heat transfer comprises a reduced parasitic near-field heat flow from the collector to the emitter.

12. The device of claim 10, wherein the collector comprises an interband emission structure having a band gap, wherein a resonant energy of the surface resonance is greater than or equal to the band gap of the collector, and wherein the enhanced net heat transfer comprises enhanced near-field heat flow from the emitter to the collector.

13. The device of claim 10, wherein the collector comprises a reverse biased intersubband structure having a transition energy Eₜ, and wherein the surface resonance of the emitter has an energy that matches Eₜ.

14. The device of claim 10, wherein the emitter comprises a non-polar material configured to diminish the surface resonance.

15. The device of claim 10, wherein the emitter comprises a polar material configured to enhance the surface resonance.

16. The device of claim 10, wherein the emitter comprises a nanostructured or microstructured surface configured to enhance the surface resonance.

17. The device of claim 10, wherein the emitter comprises a strained structure configured to enhance the surface resonance.

18. The device of claim 10, wherein the surface resonance is selected from the group consisting of: surface plasmons and surface phonon-polaritons.
